(19) United States
(12) Patent Application Publication
(10) Pub. No.: US 2024/0330528 A1
(43) Pub. Date: Oct. 3, 2024

(54) ITERATIVE METHOD FOR RECONSTRUCTING THE TOPOLOGY OF A CABLE NETWORK

(71) Applicant: COMMISSARIAT A L’ENERGIE ATOMIQUE ET AUX ENERGIES ALTERNATIVES, PARIS (FR)

(72) Inventors: Vincent SCHELLEKENS, GIF-SUR-YVETTE (FR); Jaume BENOIT, GIF-SUR-YVETTE (FR); Marie-Bénédicte JACQUES, GIF-SUR-YVETTE (FR)

(21) Appl. No.: 18/618,650

(22) Filed: Mar. 27, 2024

(30) Foreign Application Priority Data
Mar. 29, 2023 (FR) 2303037

(51) Int. Cl. G06F 30/18; G01R 31/58; G06F 30/20

(52) U.S. Cl. CPC G06F 30/18; G01R 31/58; G06F 30/20

(57) ABSTRACT

An iterative method for reconstructing the topology of a cable network, includes the following steps: obtaining a measured time-domain reflectogram, searching for a cable network topology model corresponding to the measured reflectogram by executing, based on an initial topology model, multiple iterations of at least two successive steps of transforming a topology model: i. a first step of optimizing the non-optimized branches of at least one topology model saved in the previous iteration, the optimization relating at least to the length of the branches and/or the impedance of the end-of-branch loads, ii. a second step of generating new topology models by replacing an end-of-branch load of a topology model saved after the first optimization step with a junction to multiple non-optimized branches.

### CROSS-REFERENCE TO RELATED APPLICATION

This application claims priority to foreign French patent application No. FR 2303037, filed on Mar. 29, 2023, the disclosure of which is incorporated by reference in its entirety.

### FIELD OF THE INVENTION

The invention relates to the field of the technical analysis and monitoring of complex cable networks. More specifically, it relates to a method for reconstructing the topology of a cable network. The invention aims to propose a method for determining the topology of a network, that is to say the junction points between multiple cables, the number of cables connected at each point and their respective lengths, but also the end-of-cable load impedances. The proposed method is based on the use of a time-domain reflectogram obtained by injecting a controlled signal into the cable network and then by measuring the signal reflected from the various impedance discontinuities of the network. The invention thus relates more broadly to the field of what are known as reflectometry methods, which aim to provide information about a cable or a cable network based on a reflectogram.

### BACKGROUND

Cables are ubiquitous in all electrical systems, for supplying power or for transmitting information inside buildings or vehicles such as aircraft. These cables are subject to the same constraints as the systems that they connect, and may be subject to failures. It is therefore necessary to be able to analyse their state and provide information about the detection of defects, but also their location and their type, in order to help with maintenance. Conventional reflectometry methods enable this type of test.

Reflectometry methods use a principle similar to that of radar: an electrical signal, the probe signal or reference signal, which more often than not is a high-frequency or wideband signal, is injected at one or more locations of the network to be tested. The signal propagates through the cable or the network and returns some of its energy when it encounters an electrical discontinuity. An electrical discontinuity may result for example from a junction or end-of-cable load or more generally from a break in the conditions of propagation of the signal through the cable.

Analysing the signals returned to the point of injection makes it possible to deduce therefrom information about the presence and the location of these discontinuities, corresponding to characteristic points of the topology of the network. Analysis in the time or frequency domain is usually carried out. These methods are denoted by the acronyms TDR, from the expression “time-domain reflectometry”, and FDR, from the expression “frequency-domain reflectometry”.

The invention is applicable to any type of cable network, notably electric cables, in particular power transmission cables or communication cables, in fixed or mobile installations. The cables in question may be coaxial, two-wire, parallel-line, twisted-pair or other cables, provided that it is possible to inject a reflectometry signal into them at one point of the cable network and measure its reflection at the same point or at another point.

### SUMMARY OF THE INVENTION

The object of the present invention is notably to make it possible to reconstruct the topology of complex cable networks the plans of which are not available or for which an urgent intervention requires immediate knowledge of the topology of the network. This type of problem exists notably for electricity cable or power cable networks inside a building or inside a vehicle. A technician wishing to troubleshoot the network after an electrical problem has been detected may need precise knowledge of the topology of the network to help them formulate their diagnosis. Moreover, some buildings have a level of confidentiality that by nature prohibits their electricity network plans from being disclosed.

The prior art includes various solutions that aim to determine a topology of a cable network based on a reflectometry measurement.

Patent application WO2019/030246 by the Applicant describes a first type of method for reconstructing a topology of a cable network based on a reflectometry measurement. This method is based on optimization via a genetic algorithm. One drawback of this approach is that its behaviour is highly random, and might not converge or converge very slowly for some particular cable network topologies. Moreover, the result is non-deterministic, that is to say it does not always generate the same solution from the same reflectogram.

Patent application WO2019/034497 by the Applicant describes another type of method based on a greedy iterative algorithm. This second approach is sensitive to local optima and therefore exhibits a non-negligible risk of convergence on incorrect solutions.

There is therefore a need to solve the drawbacks of the methods from the prior art in order to improve the reliability or robustness of methods based on greedy algorithms and improve the convergence speed of methods based on genetic algorithms.

The proposed method aims to progressively construct a set of “candidate” cable network models by storing in memory certain solutions in order to improve them so as to avoid convergence on local optima that do not correspond to the real solution.

The invention makes it possible to ensure the most optimum possible compromise between convergence speed and robustness.

The proposed method is based on the iterative execution of various functions that aim to evolve an initial network model by optimizing the values of the lengths of the branches and of the end-of-branch load impedances and by adding junctions progressively.

One advantage afforded by the invention is the possibility of carrying out multiple iterations of the method while widening the scope of the solutions to be explored among those stored in memory in the previous iterations.

The invention thus enables rapid convergence for easy-to-detect network structures and leaves the possibility of slower convergence for more complex structures. In all cases, the method is deterministic and exhibits a higher level of reliability than the abovementioned methods from the prior art in that it makes it possible to correctly reconstruct the topology of any network in the vast majority of cases.

One subject of the invention is an iterative, computer-implemented method for reconstructing the topology of a cable network, the method comprising the following steps:
Obtaining a measured time-domain reflectogram based on a signal injected beforehand into the cable network,
Searching for a cable network topology model corresponding to said measured reflectogram by executing, based on an initial topology model, multiple iterations of at least two successive steps of transforming a topology model:
   i. A first step of optimizing the non-optimized branches of at least one topology model saved in the previous iteration, the optimization relating at least to the length of the branches and/or the impedance of the end-of-branch loads,
   ii. A second step of generating new topology models by replacing an end-of-branch load of a topology model saved after the first optimization step with a junction to multiple non-optimized branches,
Each transformation step involving computing a cost function representative of an error between the measured time-domain reflectogram and a simulated reflectogram based on a topology model,
At the end of each transformation step, saving the topology models for which the ratio between the cost function computed for the model obtained after transformation and that computed for the model before transformation, referred to as relative improvement value, is less than a maximum value of a predetermined threshold.

According to one particular aspect of the invention, each of the two transformation steps comprises selecting, from among the saved models, those for which the relative improvement value is less than a current value of the predetermined threshold.

According to one particular aspect of the invention, the first optimization step comprises, for each branch of a topology model to be optimized, computing multiple relative improvement values for various branch length hypotheses and/or various load impedance value hypotheses.

According to one particular aspect of the invention, the second step of generating new topology models comprises, for each new topology model optimized by the first optimization step, computing multiple relative improvement values for various values of the number of non-optimized branches connected to a modelled junction as a replacement for an optimized end-of-branch load.

According to one particular aspect of the invention, the predetermined threshold has a different value for each of the two transformation steps.

According to one particular aspect of the invention, the value of the predetermined threshold for the first optimization step is less than 1, for example between 0.5 and 0.99.

According to one particular aspect of the invention, the value of the predetermined threshold for the second generation step is greater than 1, for example between 1.01 and 1.2.

In one variant embodiment, the method according to the invention comprises, when the number of branches n of a topology model generated by the second generation step reaches a predefined maximum value N, a new iteration of all of the steps of the method while increasing the current value of the predetermined threshold for at least one of the transformation steps.

In one variant embodiment, the method according to the invention furthermore comprises an additional step of optimizing the topology models optimized by the first optimization step by searching, for each parameter to be optimized, over a predefined interval centred on the value of said parameter, for a modified value that minimizes the cost function over the interval.

In one variant embodiment, the method according to the invention furthermore comprises a third step of transforming a topology model consisting in adding, to a branch of a topology model saved in the previous step, a new junction at a variable position and, for each new topology model optimized in the previous steps, computing multiple relative improvement values for various values of said position.

In one variant embodiment, the method according to the invention comprises a step of stopping the method when the cost function computed for at least one topology model is less than a predetermined stop threshold.

In one variant embodiment, the method according to the invention comprises a step of displaying the reconstructed topology of the cable network on a display device.

In one variant embodiment, the method according to the invention comprises a preliminary step of injecting the signal into the cable network.

Another subject of the invention is a computer program comprising instructions for executing the method for reconstructing the topology of a cable network according to the invention when the program is executed by a processor.

Another subject of the invention is a processor-readable recording medium on which there is recorded a program comprising instructions for executing the method for reconstructing the topology of a cable network according to the invention when the program is executed by a processor.

### BRIEF DESCRIPTION OF THE DRAWINGS

Other features and advantages of the present invention will become more clearly apparent on reading the following description with reference to the following appended drawings.

FIG. 1 shows a diagram illustrating the general problem addressed by the invention,

FIG. 2 shows a flowchart detailing the steps for implementing a topology reconstruction method according to one embodiment of the invention,

FIG. 3 shows a table storing a set of intermediate solutions obtained during the iterations of the method according to the invention,

FIG. 4a shows one example of a measured time-domain reflectogram,

FIG. 4b shows one example of a search area for parameters to be optimized,

FIG. 5 shows a flowchart detailing one exemplary implementation of an optimization step of the method according to the invention,

FIG. 6 shows a flowchart detailing one exemplary implementation of a step of generating new topology models of the method according to the invention,

FIG. 7a shows one example of a network topology correctly reconstructed by the invention,

FIG. 7b shows, for the same example, a result obtained via an iterative approach from the prior art,

FIG. 8 shows one example of a system able to carry out the invention.

### DETAILED DESCRIPTION

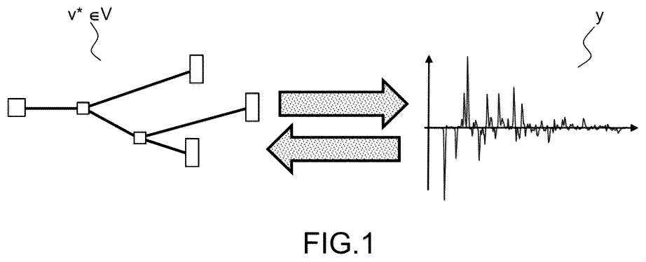

FIG. 1 schematically shows the general problem addressed by the invention. This problem consists in determining the topology of an unknown cable network ν*∈V based on a reflectogram measurement y obtained for this network.

The topology of a cable network is defined notably by its number of branches, the length of each branch, the value of the impedance of the loads at the end of each branch, and the junctions between various branches. Without departing from the scope of the invention, other parameters may be taken into account, such as the physical characteristics specific to each cable.

The general problem to be solved may be seen as an optimization problem that consists in finding the solution

$$\hat{v} = {min}_{v ∈ V} C ( v )$$

that makes it possible to minimize a cost function C that is characteristic of an error or of a distance between the measured reflectogram y and a simulated reflectogram S(v) based on a network topology model v.

For example, the cost function C is defined by a distance between the two reflectograms C(ν)=∥S(ν)−y∥₂.

As is otherwise known, a reflectometry measurement is obtained by injecting a controlled signal at one point of the cable network and then by measuring, at the same point or at a different point of the network, the signal that is backpropagated after having undergone multiple reflections from impedance discontinuities appearing in the cables of the network. The reflectometry measurement may be obtained by way of a measuring device comprising a signal generator, a digital-to-analogue converter, a coupler for injecting the analogue signal into the cable and measuring its reflection, an analogue-to-digital converter, a processor and a memory for computing the reflectogram and saving it. The signal that is used may be of a diverse nature: it may be a simple Gaussian signal, a time slot or a pulse or else a more complex signal. Depending on the exact nature of the signal, the time-domain reflectogram is obtained directly by measuring the backpropagated signal or else by computing a cross-correlation between this measurement and a copy of the signal injected into the network. In general, any signal measurement comprising information relating to the reflections of the signal from the singular points of the network, that is to say the junctions and the end-of-cable loads, is compatible with the invention. It should be noted that measuring the time-domain reflectogram requires access to only a single test port of the network.

To simulate a time-domain reflectogram based on the definition of a cable network topology, it is also known to model the propagation of the signal from the impedance discontinuities corresponding to the singular points of the network, for example based on telegrapher's equations that make it possible to describe the evolution of voltage and current on an electricity line as a function of distance and time.

$$\frac{\partial v ( x , t )}{\partial x} = - Ri ( x , t ) - L \frac{\partial i ( x , t )}{\partial t} \qquad ( 1 )$$

$$\frac{\partial i ( x , t )}{\partial x} = - Gv ( x , t ) - C \frac{\partial v ( x , t )}{\partial t} \qquad ( 2 )$$

The parameters R, L, C, G correspond to the resistance, inductance, capacitance and conductance of the line, respectively.

The invention thus aims to propose a novel optimization method that makes it possible to iteratively find the optimum solution v that minimizes the cost function C(v).

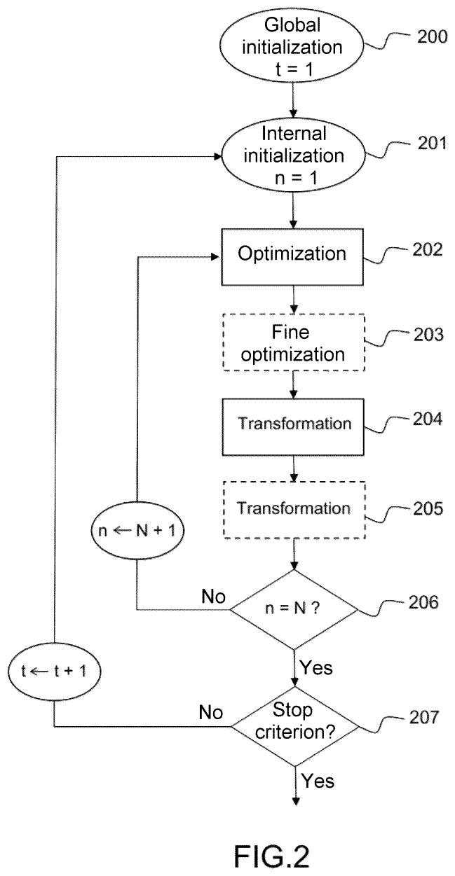

FIG. 2 describes, on a flowchart, the steps for implementing the invention in one exemplary embodiment.

The proposed method is iterative and, as indicated in FIG. 2, works in two loops of iterations on the variables t and n, respectively.

The variable n corresponds to the number of branches of a network topology model, n varying from 1 to N, where N is the maximum number of branches permitted for the search for the optimum topology model corresponding to a measured reflectogram.

The variable t corresponds to a constraint level relating to the space of the solutions saved in memory and that are permitted to be explored again in the current iteration. The variable t varies from 1 to T, where T corresponds to the lowest constraint level for which it is permitted to explore all of the solutions saved in memory. Levels t below T correspond to higher constraint levels for which the space of the explored solutions is reduced.

One advantage of iterative operation on the variable t is that it allows fast convergence when the topology being sought is simple, while at the same time keeping a robust (albeit slower) convergence when the topology being sought is complex.

In other words, the variable t controls the dynamic evolution of an explorability criterion for the solutions. It evolves from t=1, corresponding to a very stringent criterion for which only the most promising solutions are considered, to the maximum level t=T, corresponding to the least stringent criterion for which all of the saved solutions are considered.

Considering a solution means starting from this solution so as to optimize it or modify it in order to generate one or more other new solutions.

Typically, the iteration t=t+1 is reached when, at the stage t, no satisfactory solution has been found and a search among less promising solutions is permitted. The iteration t=T is reached when, at this stage, a search is permitted among all of the least promising remaining solutions.

The method starts in step 200 with the initialization of the variable t at 1, this corresponding to the highest constraint level.

The initialization step 200 comprises acquiring a measurement of a reflectogram obtained on a cable network the topology of which is unknown and is desired to be retrieved. It also comprises defining an initial network topology model based on which the optimization search will begin, this model being for example a simple model consisting of a single non-optimized branch.

In step 201, for each new iteration on the variable t, the variable n is initialized at 1, this corresponding to a topology model with a single branch. This initially comprises an initial topology model with a single non-optimized branch.

Step 201 also comprises setting exploration thresholds that depend on the iteration t, as will be described in more detail below.

The exploration thresholds are acceptance thresholds for solutions produced by transformation. A maximum number of solutions to be considered depending on the iteration t is also set.

A non-optimized branch is a branch the length and end-of-branch load impedance of which are unknown.

A non-optimized branch may be modelled by a matched branch, that is to say a cable terminated by a load of impedance equal to the characteristic impedance of the cable, this corresponding to an absence of reflection of the signal and therefore of a corresponding peak on the simulated reflectogram.

In each iteration on the variable n, multiple steps 202, 203, 204, 205 of transforming the initial topology model are carried out so as to produce one or more new model solutions that may correspond to the topology being sought. The variable n defines the number of branches of the models explored in the current iteration.

In step 206, when the maximum number of branches N is reached, there is a transition to step 207, in which a criterion for stopping the algorithm is executed to check whether one of the generated models has a cost function less than a given threshold, in which case this model is retained as the final solution. Otherwise, there is a transition to a new iteration on the variable t while relaxing the exploration constraints for the saved solutions.

A more detailed description is now given of each of the steps of transforming a topology model.

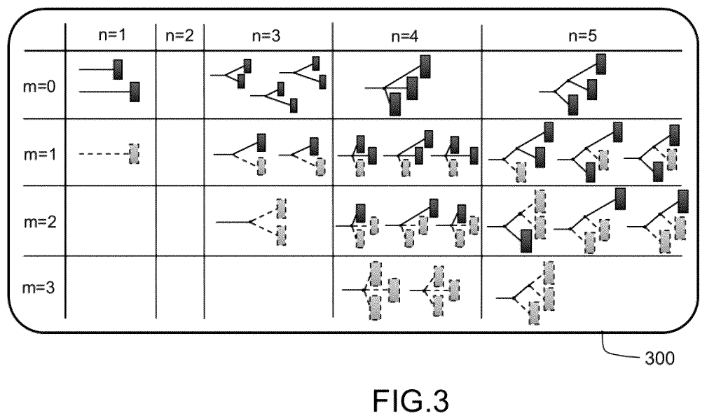

For this purpose, a representation of the topology model solutions saved in the form of a table 300 shown in FIG. 3 is taken as a basis.

The solutions obtained after each transformation step are saved in the cells of the table 300 according to the total number of branches n of the model (corresponding to the columns of the table) and to the number of non-optimized branches m of the model (corresponding to the rows of the table).

In the example in FIG. 3, n varies from 1 to 5 and m varies from 0 to 3.

The method begins with a simple initial topology model, for example a model with a single non-optimized branch represented in the cell (n=1,m=1) of the table 300.

In FIG. 3, the various exemplary network topologies are given purely by way of illustration in order to explain the operation of the invention with reference to an example.

The non-optimized branches are represented in dotted lines, while the branches that have already been optimized are represented in solid lines.

Step 202 is an optimization step that aims to optimize non-optimized branches of the topology models generated in the previous iterations and saved in the column of index n of the table 300.

More specifically, step 202 aims to find local minima for the cost function by varying the branch length parameter and end-of-branch load impedance value parameter.

The parameter search ranges are defined according to the nature of the measured reflectogram.

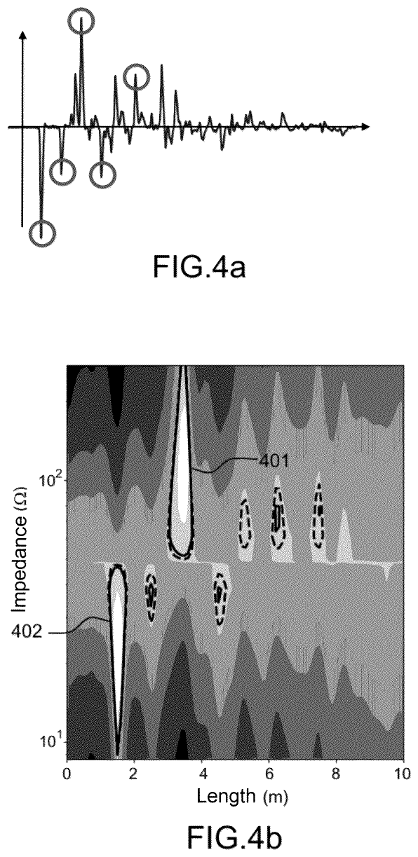

By way of example, FIG. 4a shows a measured time-domain reflectogram on which there are identified multiple amplitude peaks that potentially correspond to loads or junctions of the network.

FIG. 4b shows a search grid for the respective branch length parameter (on the abscissa) and end-of-branch load impedance parameter (on the ordinate). The sought values are preferably concentrated in zones corresponding to the peaks of the reflectogram.

For a current iteration on the index n, we focus on the corresponding column of index n of the table 300, and the optimization starts from the highest value of m for which at least one topology model has previously been generated.

For example, initially for n=1, the starting point is the cell (m=1,n=1) in which a model consisting of a single non-optimized branch is saved.

In the iterations on higher values of n, for example at n=4, the starting point is the cell (m=3,n=4) in which multiple models consisting of multiple non-optimized branches that have been obtained in a previous iteration are saved.

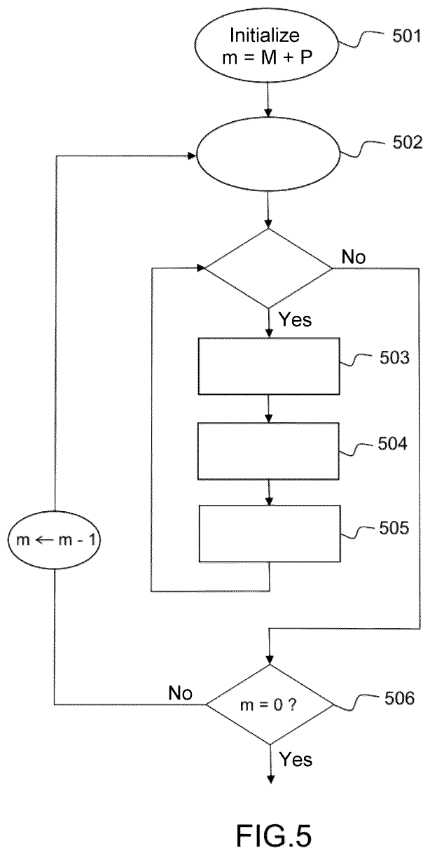

FIG. 5 schematically shows one exemplary implementation of an optimization algorithm executed in step 202 of the method of FIG. 2.

In step 501, the algorithm is initialized by setting the value of m (index of a row of the table 300) to m=M+P.

M is the maximum number of non-optimized branches accepted in the transformation step 204. In one preferred embodiment, M is taken to be equal to 0, but it may generally be chosen to be greater than or equal to 1 in order to explore the space of the solutions in a more exhaustive manner.

P is the maximum number of non-optimized branches added in the transformation step 204.

M+P is therefore equal to the maximum number of non-optimized branches that a solution may have after the operation 204. Thus, m corresponds to the index of the last possible row in the table-based representation of the solutions 300.

In step 502, the solutions able to be explored in the iteration of index t are retrieved from the cell of index (m,n) of the table 300. These are all of the solutions that satisfy an explorability criterion.

An explorability criterion is defined in each iteration so that each step of the algorithm explores certain previously found solutions, but not all of them, in order to limit computational complexity.

The explorability criterion determines whether a solution v may be explored by an operation. One example of a criterion consists in satisfying the following three conditions.

First of all, the retained solution v has not yet been explored by the operation in question in a previous iteration.

Next, the solution v is promising in the sense that its relative improvement value I(v) does not exceed an acceptance threshold defined according to the iteration t.

The relative improvement value depends on the previous solution v′ and on a cost function C.

It is given for example by the relationship

$$I ( v ) = \frac{c ( v )}{c ( {v}^{′} )} .$$

The cost function C is for example equal to a distance between the measured reflectogram and a simulated reflectogram based on the topology model v.

A solution v is retained for exploration if its relative improvement value is greater than an acceptance threshold that depends on the operation and on the iteration t.

For the optimization operation 202, the acceptance threshold θₜ^{O} is preferably chosen to be less than 1 and for example between 0.5 and 0.99.

Moreover, its value increases as a function of the iterations on t. For example, θ₁^{O}-0.8 and θ_{T}^{O}=0.98 and the value of the threshold increases between these two bounds as a function of the value of the iteration t.

The value of the acceptance threshold for the optimization operation is less than 1, because it is expected that a significant reduction in the cost function will be able to be achieved by introducing a new peak into the simulated reflectogram.

Step 502 therefore determines a list L of solutions to be explored in the cell (n,m) of the table 300, these solutions all having a relative improvement value that is strictly less than the acceptance threshold θₜ^{O}. Depending on the iteration t, the chosen threshold will be higher or lower, thereby leading to a change in the constraints and therefore a larger or smaller solution search space to be explored. At most, the number of solutions retained in the list L in step 502 is equal to the number of solutions stored in the cell (n,m) of the table 300.

This parameter of the invention thus makes it possible to obtain the best compromise between execution speed and convergence speed (in the first iterations on t) and robustness due to the exploration of solutions in a larger space (in the last iterations on t).

If the number of solutions in the list L is not zero, there is a transition to step 503 in order to browse the list of solutions and provide the next solution v to be processed.

In step 504, the non-optimized branches of the topology model of the solution v are sought.

β₁, . . . , βₘ denotes the one (or more, if m>1) matched branches of the network ν.

If multiple matched branches start from the same junction, typically for a network to which an operation of adding multiple branches has just been applied, only one of these matched branches is kept at the output of step 504. Each of the branches βᵢ therefore starts from a different junction.

It should be noted that, more often than not (that is to say when M=0), there will be only one matched branch β₁ because, in this case, the only matched branches necessarily result from an operation of adding branches, and they are therefore all located at the same junction. However, if M>0 has been set, it is possible to have solutions with non-optimized branches starting from multiple junctions (m>1).

In step 505, the branch βᵢ provided as input is then optimized. This optimization consists in determining at least one parameter among the length of the branch and the value of the impedance of the load at the end of the branch.

In this operation 505, multiple solutions may be retained, in a maximum number equal to J. All of the new solutions that are obtained are added to the cell (n,m−1) of the table 300. Indeed, when optimizing a branch, the number of non-optimized branches m is decremented.

The optimization operation 505 consists for example in carrying out one or more of the following sub-steps.

The cost function C(v) is computed for a set of branch length values I and end-of-branch load impedance values Z on a grid, as defined for example in FIG. 4b.

More specifically, the search grid may be defined as follows:
For the branch lengths, consideration is given to all lengths between l=Lₘᵢₙ and l=Lₘₐₓ (a maximum cable length that the user must define), in linear increments of a parameter L_{coarse}. For example, Lₘᵢₙ=0.
For the load impedances, rather than varying the value linearly in the “natural” range of the impedance Z, one possibility is to vary it linearly in the range of the associated reflection coefficients, this being more appropriate given the physical meaning of the reflectometry measurements. More precisely, consideration is given to all reflection coefficients Γ between −1 and +1 in linear increments of Γ_{course}, and then the value of the associated impedance Z is deduced therefrom via the relationship

$$Z = Z ( Γ ) = {Z}_{0} \frac{1 + Γ}{1 - Γ}$$

(where Z₀ denotes the characteristic impedance of the cable).
For each cable length value l and reflection coefficient Γ of the end-of-line load thus obtained, the associated reflectogram is simulated and compared with the reference reflectogram in order to obtain the value of the cost function, denoted C(l, Γ) or C(l, Z) here.

Once the cost function is known on the grid, it is necessary to deduce therefrom the local minima, this being done by following the following procedure.

A restriction is drawn only to positions on the grid (L, Γ) the computed cost C(L, Z) of which satisfies C(L, Z)≤θ_{T}^{o}×C(ν′), where C(ν′) therefore denotes the cost of the network before the start of the optimization step (where the branch under consideration is not optimized, and therefore modelled as a matched branch). θ_{T}^{o} is the maximum acceptance threshold beyond which it is considered that the solutions are too far from the model being sought and it is not useful to save them.

These positions are organized in a graph in which each position (L, Γ) is connected to neighbours on the grid: (L−L_{coarse}, Γ), (L+L_{coarse}, Γ), (L, Γ−Γ_{coarse}), and (L, Γ+Γ_{coarse}) (only if these solutions have also been selected for their promising cost).

It is then determined what the connected components in this graph are, that is to say the neighbourhoods of interconnected selected solutions. For example, in the illustration in FIG. 4b, each connected component is surrounded by a solid line 401, 402. A connected component is obtained through a local optimum of the cost function, and therefore J connected components in all.

For each connected component 401, 402, its minimum is sought locally. In other words, among all of the positions in the connected component 401, 402, the position (L, Z) with the lowest cost is chosen, using the computing of the cost function C(L, Z), and a new solution is deduced therefrom. This gives a total of J new solutions, one per local minimum.

Each new solution is added by following a procedure of recording new networks, which consists in recording, in addition to the topology model that is obtained, the value of the cost function and the relative improvement value, and in checking whether this solution does not already exist in the table 300.

In general, step 505 makes it possible to obtain multiple new optimized solutions from each previously saved model that comprises at least one non-optimized branch.

Returning to the example of FIG. 3, it may be seen that, starting from the initial solution stored in (m=1,n=1), two optimized solutions are determined for the cell (m=0,n=1), which correspond to two different solutions of a network with a single branch and a load.

The same principle is illustrated for the other columns of the table 300.

The highest value of m for each column corresponds to the number of branches that have not yet been optimized and that are progressively optimized by decrementing the value of m and moving up the cells of the table.

For example, for (m=2,n=3), there is a network with 3 branches, 2 branches of which are not optimized.

The optimization step 505 makes it possible to generate two new solutions at (m=1,n=3) of networks with 3 branches, each of which now has only a single non-optimized branch.

Finally, three solutions (at m=0,n=3) are obtained for networks with three branches, two branches of which terminate in a load having an optimized value.

The same principle is applied for networks with 4 branches (n=4) and 5 branches (n=5) in the example in FIG. 3.

Steps 503, 504, 505 are iterated over the entire list L and then, when this list is empty, the index m is decremented by 1, and then step 502 is returned to until the value of m is zero (step 506).

At the end of the optimization step 202, the cells of the table 300 are filled, for the current column of index n, with one or more cable network topology solutions.

An optional step 203 may then be applied to refine the optimization results obtained in the previous step. This step does not produce any new network topologies, but may modify the parameters of the topologies already present in the table 300.

Similarly to step 202, the fine optimization step 203 begins with retrieving the list of explorable solutions, which corresponds to the list of networks stored in the table 300 in the column of index n and in the row m=0 (all of the branches have been optimized) and that meet the explorability criterion described above.

Unlike optimization step 202, in this step 203, it is permitted to directly modify all of the parameters, namely the lengths of the branches and the end-of-branch load impedances for one and the same network. This makes it possible to improve the first parameters that are found (for high values of m) by taking into account those that are found later (for low values of m).

Once the networks that will be refined have been selected, the fine optimization step 203 is carried out by way of a recursive algorithm that takes a parameter to be optimized (length or impedance) as argument.

Initially, the algorithm is executed on the first branch of the network (the one furthest upstream).

The algorithm determines whether the parameter given as argument is a cable or else an impedance.

If it is a cable, the length of which is L, its length is varied between max(0, L−L_{coarse}) and min(Lₘₐₓ, L+L_{coarse}) in increments of L_{fine}, where L_{coarse} and L_{fine} are predefined parameters.

If it is an impedance the value of which corresponds to a reflection coefficient, Γ, the load is varied so as to have a reflection coefficient between max(−1+Γ_{coarse}, Γ−Γ_{coarse}) and min(+1−Γ_{coarse}, Γ+Γ_{coarse}) in increments of Γ_{fine}, where Γ_{coarse} and Γ_{fine} are predefined parameters.

The value of the cost function is computed for each new configuration, and the one that minimizes the cost function is retained.

Next, the optimization algorithm is called recursively on the other branches of the network that are connected at the end of the line of the branch that has already been processed (if there is one); in other words, there is progression down the network.

The fine optimization step 203 makes it possible to refine the values of the length and impedance parameters determined in step 202 on a finer search grid. Indeed, in step 202, the search is carried out on a grid the pitch of which is given by the values L_{coarse} and Γ_{coarse} whereas, in step 203, the search is carried out on a grid the pitch of which is given by the values L_{fine} and Γ_{fine}, which are chosen to be less than the values L_{coarse} and Γ_{coarse}.

In step 204 of the method, transformations are this time applied to the stored topology models so as to replace optimized loads with junctions. Indeed, by analysing a reflectogram, it is not possible at first glance to distinguish between a reflection of the signal from an end-of-cable load and a reflection from a junction.

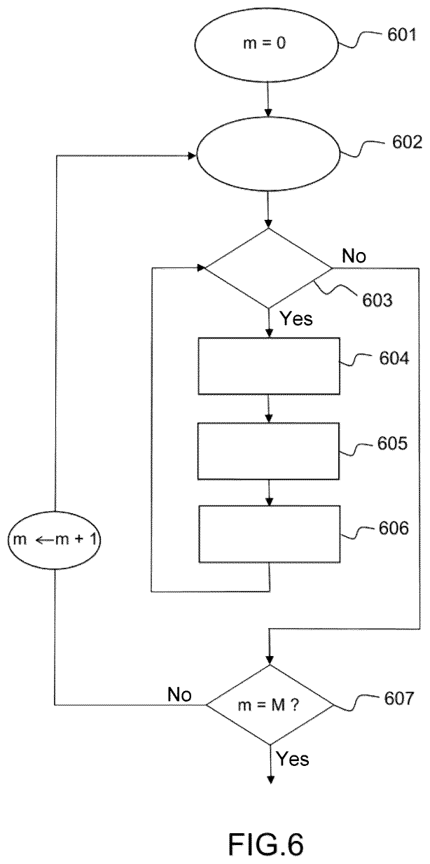

FIG. 6 details, on a flowchart, the steps for implementing one example of an algorithm executed in step 204.

The initialization steps 601 and 602 are similar to the corresponding initialization steps 501 and 502 of the optimization method described in FIG. 5.

One difference is that the outer loop on the index m is initialized at m=0 and is incremented by 1 in each new iteration. In other words, unlike optimization step 202, for this modification step 204, each column of the table 300 is processed starting with m=0 and progressing in the column from m=0 to higher values of m.

Step 602 consists in retaining the solutions that comply with a specific explorability criterion in step 204, that is to say that implements acceptance thresholds different from those used in step 202.

For the transformation step 204, the acceptance threshold θₜ^{S} is preferably chosen to be greater than 1 and, for example, between 1 and 2.

Moreover, its value increases as a function of the iterations on t. For example, θ₁^{S}=1.01 and θ_{T}^{S}=1.2 and the value of the threshold increases between these two bounds as a function of the value of the iteration t.

The value of the acceptance threshold for the optimization operation is greater than 1 because it is difficult to reduce the cost of a solution when replacing an optimized load with a rigid junction. In step 204, which aims to add rigid junctions to multiple new branches instead of an already optimized load, it is therefore permitted to temporarily worsen the cost of the new solutions that are generated.

In step 603, it is checked that the list of explorable solutions L is not empty. If it is empty, there is a transition to the following iteration on m (m=m+1), otherwise the solutions in the list L are processed in sequential order in step 604.

In step 605, for each solution retained, it is determined which loads in the network v are likely to potentially correspond to a junction. One possible criterion is to retain all loads the impedance Zⱼ of which is strictly less than the impedance Z₀ of the cable, in other words the reflection coefficient of which is negative.

Another criterion consists in retaining all loads that were optimized in preceding steps 202, 203.

Next, in step 606, multiple new network topology models are generated by replacing each load identified in step 605 with a junction to a number p of new non-optimized branches.

The number p varies from 2 to the minimum out of P and N−n. P is the maximum number of branches after a junction, which is a predetermined parameter.

The number of branches must also be less than N−n because the new network generated after step 606 will consist of n+p branches, but the total number of branches of a network must be at most equal to N.

For each value of p, the optimized load is replaced with a junction with p non-optimized branches that are simulated as branches terminated by a load matched to the impedance of the cables. These new branches therefore have no impact on the simulated reflectogram. The value of the cost function is then computed for each new network generated through simulation of the reflectogram and comparison with the measured initial reflectogram, and then only those solutions that satisfy the criterion C(ν)≤θ_{T}^{S}×C(ν′), where v′ is the previous state of the solution, are retained as candidate solutions. θ_{T}^{S} is the maximum value of the acceptance threshold beyond which it is considered that it is not necessary to save the tested solution.

The new solutions generated in step 606 are saved in the table 300 in the column of index n+p and for values of m greater than or equal to 2. These new solutions will then be optimized in a next iteration on the index n via the optimization step 202.

Step 204 of the method ends when all of the solutions stored in a column of the table 300 have been processed (m=M, step 607).

Returning to FIG. 2, the optimization method comprises yet another optional step 205 that aims to generate new solutions by adding a junction along a branch that has already been optimized.

Again, in a similar manner to the other operations, the list of candidate solutions, which correspond here to networks with n cables and no matched branch m=0, is retrieved.

For each solution under consideration, each of the branches (of length L) is run through and, for all positions along this branch (between 0 and L in linear increments of L_{coarse}), an attempt is made to add a junction (to a branch that terminates in a matched load) along this branch (for all lengths between 0 and L) in increments of L_{coarse}. Next, the loads downstream and upstream of this junction are modified so as to take into account the influence of this new junction.

The downstream loads are modified as follows: for each load that is located downstream of the network with respect to the new junction, if its reflection coefficient is denoted Γ, it is replaced with a load such that its new reflection coefficient has a higher value, for example equal to

$$\frac{9}{4} Γ ,$$

thereby making it possible to compensate for the loss of amplitude by a factor of 4/9 following the addition of a junction along the path to this load.

The cost function of this new network ν is then computed. If the cost is such that C(ν)≤θ_{T}^{S}×C(ν′) (where ν′ denotes the network before the addition of a cable start), it is added to the set of solutions in accordance with the procedure already described above.

Steps 202 to 205 are iterated for all values of n up to N, which is tantamount to progressively filling the table 300 from the column n=1 up to n=N.

Next, there is a transition to step 207, which consists in checking whether, among the set of solutions saved in the table 300, at least one solution satisfies a criterion for stopping the method. This stop criterion consists for example in comparing the cost function C(v) of each solution with a stop threshold the value of which is close to 0.

If at least one solution satisfies the stop criterion of step 207, the one that minimizes the cost function is retained. It is also possible to retrieve multiple solutions at the output of the algorithm if their cost functions are very close. In such a situation, an indicator of possible ambiguity between these solutions may be provided. If the stop criterion is not satisfied, there is a transition to a new iteration on the variable t, relaxing the constraints on the acceptance thresholds θₜ^{S} and θₜ^{O}, that is to say by increasing them so as to explore a greater number of solutions in the optimization step and the step of generating new networks.

If, at the end of all of the iterations on the variable t, no solution satisfies the stop criterion 207, the solution that minimizes the cost function is retained.

In one particular embodiment of the invention, in the step of saving a new network in the table 300, it is determined beforehand whether this new network is not identical or almost identical to a model already generated and present in the table 300.

Two network models v and v′ are considered to be almost identical if:
They have the same structure, that is to say the same number of branches and the same junctions,
If, for each branch of v and its equivalent for v′, of respective lengths L and L′, these lengths are close, i.e. |L−L′I≤Lₜₒₗ with Lₜₒₗ being a predefined parameter,
If, for each load of v and its equivalent for v′, the values of the impedances or reflection coefficients are close, that is to say if |Γ−Γ′|≤Γₜₒₗ with Γₜₒₗ being a predefined parameter.

Moreover, since the order of the branches in the junctions of ν and ν′ is arbitrary, it is possible to have two networks that are identical but the representation of which is different if the branches at the output of the junctions are permuted. This test is therefore carried out for all permutations of the branches at the output of all of the junctions of ν′.

In order to avoid a combinatorial explosion and to have an efficient implementation of these multiple comparisons, two variant embodiments are possible.

First of all, identical networks are detected recursively, starting upstream of the networks and stopping as soon as it is certain that no permutation gives a conclusive result.

In order to avoid a large number of comparisons between identical networks, the results of the various comparisons are stored, and these are automatically retrieved when the same computation has to be carried out again.

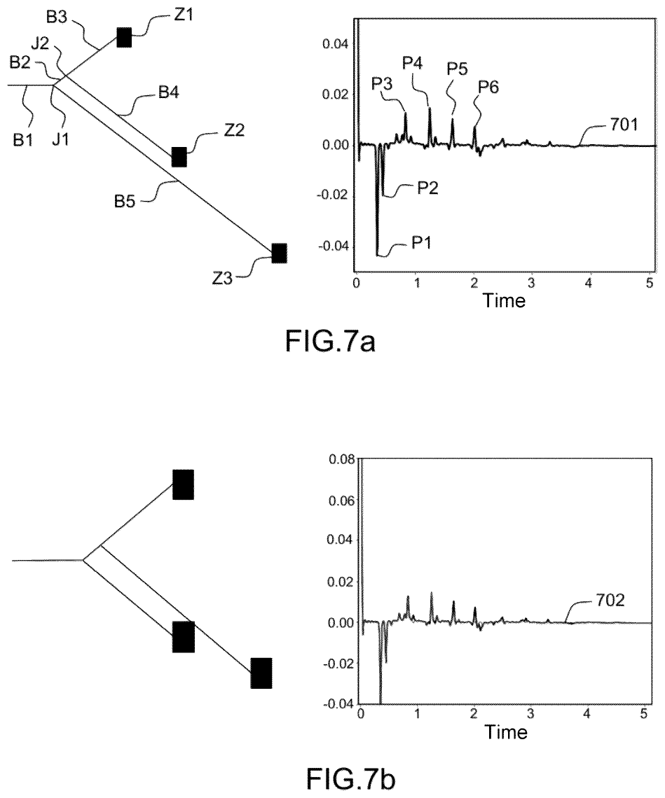

FIG. 7a illustrates one example of a result obtained by the invention for a cable network composed of five branches B1, B2, B3, B4, B5 and three loads Z1, Z2, Z3. The reflectogram 701 measured for this network is shown on the right of the figure, where multiple peaks P1, P2, P3, P4, P5, P6 corresponding to various singularities of the network have been identified.

Specifically, the first peak P1 corresponds to the reflection of the signal from the first junction J1 between the branches B1, B2 and B5.

The second peak P2 corresponds to the reflection of the signal from the second junction J2 between the branches B2, B3 and B4.

The third peak P3 corresponds to the reflection of the signal from the load Z1 at the end of the branch B3.

The fourth peak P4 corresponds to the reflection of the signal from the load Z2 at the end of the branch B4.

The fifth peak P5 corresponds to a combination of the reflections from the loads Z1 and Z2 corresponding to a path of the signal towards the load Z1 and then towards the load Z2 (and vice versa).

The sixth peak P6 corresponds to the reflection of the signal from the load Z3 at the end of the branch B5.

FIG. 7b shows the reflectogram 702 obtained by applying a greedy algorithm iterative method according to the prior art. The reflectogram 702 is shown superimposed on the measured reflectogram 701. The network topology reconstructed via this algorithm is shown on the left of the figure.

It may be seen that the branch B5 is not reconstructed correctly because the algorithm converges on a local optimum from the fifth peak P5, without taking into account the sixth peak P6, which actually corresponds to the branch B5.

In the case of a genetic algorithm, this is capable of finding the correct topology on this example, but only 1 time out of 10.

Conversely, the method according to the invention makes it possible to find exactly the right network topology for this example and to do so systematically with a convergence time greater than that of the iterative approach, but which makes it possible to output a reliable result due to a wider exploration of the possible solutions.

The method according to the invention may be implemented as a computer program, the method being applied to a reflectometry measurement acquired beforehand using a conventional reflectometry device. The invention may be implemented as a computer program comprising instructions for the execution thereof. The computer program may be recorded on a processor-readable recording medium. The reference to a computer program that, when it is executed, performs any one of the functions described above is not limited to an application program running on a single host computer. On the contrary, the terms computer program and software are used here in a general sense to refer to any type of computer code (for example application software, firmware, microcode, or any other form of computer instruction) that may be used to program one or more processors to implement aspects of the techniques described here. The computing means or resources may notably be distributed (“Cloud computing”), possibly using peer-to-peer technologies. The software code may be executed on any suitable processor (for example a microprocessor) or processor core or set of processors, be these provided in a single computing device or distributed among multiple computing devices (for example as possibly accessible in the environment of the device). The executable code of each program allowing the programmable device to implement the processes according to the invention may be stored for example in the hard drive or in read-only memory. Generally speaking, the one or more programs will be able to be loaded into one of the storage means of the device before being executed. The central processing unit is able to command and direct the execution of the software code portions or instructions of the one or more programs according to the invention, which instructions are stored in the hard drive or in the read-only memory or else in the other abovementioned storage elements.

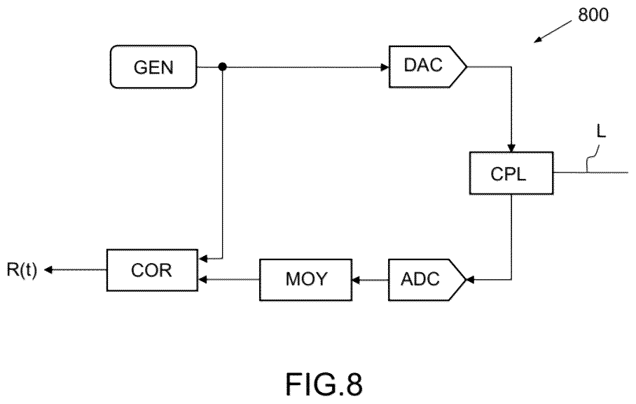

As an alternative, the invention may also be implemented in an embedded device as described in FIG. 8, furthermore comprising a computer configured to execute the method according to the invention in order to provide, based on a measured reflectogram, one or more probable topologies of the network under test. The device may also comprise a means for displaying the results of the method in the form of a graph or in numerical form.

To this end, FIG. 8 shows a diagram of a reflectometry system 800 connected to a transmission line L (shown as a single line in FIG. 8, but which may be a more complex cable network), such as a cable, and configured to carry out a time-domain reflectometry measurement. Such a system primarily comprises a generator GEN for generating a reference signal. The generated digital reference signal is converted to analogue via a digital-to-analogue converter DAC and is then injected at a point of the transmission line L by way of a directional coupler CPL or any other device for injecting a signal into a line. The signal propagates along the line and is reflected from the singularities that said line contains. In the absence of a defect on the line, the signal is reflected from the singularities of the cable network. The reflected signal is backpropagated to a measurement point, which may be the same as the injection point or different. The backpropagated signal is measured via the directional coupler CPL and then converted to digital by an analogue-to-digital converter ADC. A correlation COR may be carried out (depending on the type of signal used) between the measured digital signal and a copy of the digital signal generated before injection in order to produce a time-domain reflectogram R(t) corresponding to the cross-correlation between the two signals.

1. An iterative, computer-implemented method for reconstructing the topology of a cable network, the method comprising the following steps:
obtaining a measured time-domain reflectogram based on a signal injected beforehand into the cable network,
searching for a cable network topology model corresponding to said measured reflectogram by executing, based on an initial topology model, multiple iterations of at least two successive steps of transforming a topology model:
i. a first step of optimizing the non-optimized branches of at least one topology model saved in the previous iteration, the optimization relating at least to the length of the branches and/or the impedance of the end-of-branch loads,
ii. a second step of generating new topology models by replacing an end-of-branch load of a topology model saved after the first optimization step with a junction to multiple non-optimized branches,
each transformation step involving computing a cost function representative of an error between the measured time-domain reflectogram and a simulated reflectogram based on a topology model,
at the end of each transformation step, saving the topology models for which the ratio between the cost function computed for the model obtained after transformation and that computed for the model before transformation, referred to as relative improvement value, is less than a maximum value of a predetermined threshold.

2. The method for reconstructing the topology of a cable network according to claim 1, wherein each of the two transformation steps comprises selecting, from among the saved models, those for which the relative improvement value is less than a current value of the predetermined threshold.

3. The method for reconstructing the topology of a cable network according to claim 1, wherein the first optimization step comprises, for each branch of a topology model to be optimized, computing multiple relative improvement values for various branch length hypotheses and/or various load impedance value hypotheses.

4. The method for reconstructing the topology of a cable network according to claim 1, wherein the second step of generating new topology models comprises, for each new topology model optimized by the first optimization step, computing multiple relative improvement values for various values of the number of non-optimized branches connected to a modelled junction as a replacement for an optimized end-of-branch load.

5. The method for reconstructing the topology of a cable network according to claim 1, wherein the predetermined threshold has a different value for each of the two transformation steps.

6. The method for reconstructing the topology of a cable network according to claim 5, wherein the value of the predetermined threshold for the first optimization step is less than 1, for example between 0.5 and 0.99.

7. The method for reconstructing the topology of a cable network according to claim 5, wherein the value of the predetermined threshold for the second generation step is greater than 1, for example between 1.01 and 1.2.

8. The method for reconstructing the topology of a cable network according to claim 1, comprising, when the number of branches n of a topology model generated by the second generation step reaches a predefined maximum value N, a new iteration of all of the steps of the method while increasing the current value of the predetermined threshold for at least one of the transformation steps.

9. The method for reconstructing the topology of a cable network according to claim 1, furthermore comprising an additional step of optimizing the topology models optimized by the first optimization step by searching, for each parameter to be optimized, over a predefined interval centred on the value of said parameter, for a modified value that minimizes the cost function over the interval.

10. The method for reconstructing the topology of a cable network according to claim 1, furthermore comprising a third step of transforming a topology model consisting in adding, to a branch of a topology model saved in the previous step, a new junction at a variable position and, for each new topology model optimized in the previous steps, computing multiple relative improvement values for various values of said position.

11. The method for reconstructing the topology of a cable network according to claim 1, comprising a step of stopping the method when the cost function computed for at least one topology model is less than a predetermined stop threshold.

12. The method for reconstructing the topology of a cable network according to claim 1, comprising a step of displaying the reconstructed topology of the cable network on a display device.

13. The method for reconstructing the topology of a cable network according to claim 1, comprising a preliminary step of injecting the signal into the cable network.

14. A computer program comprising instructions for executing the method for reconstructing the topology of a cable network according to claim 1 when the program is executed by a processor.

15. A processor-readable recording medium on which there is recorded a program comprising instructions for executing the method for reconstructing the topology of a cable network according to claim 1 when the program is executed by a processor.
